(19) United States
(12) Patent Application Publication
(10) Pub. No.: US 2026/0101787 A1
(43) Pub. Date: Apr. 9, 2026

(54) SEMICONDUCTOR PACKAGE INCLUDING A DAM STRUCTURE

(71) Applicant: SAMSUNG ELECTRONICS CO., LTD., SUWON-SI (KR)

(72) Inventors: Inhee Yoo, Suwon-si (KR); Seoeun Kyung, Suwon-si (KR)

(21) Appl. No.: 19/215,667

(22) Filed: May 22, 2025

(30) Foreign Application Priority Data
Oct. 7, 2024 (KR) 10-2024-0135686

(51) Int. Cl. H01L 23/00; H01L 23/13; H01L 23/31; H01L 25/16

(52) U.S. Cl. CPC H10W 70/68; H10W 74/111; H10W 90/00; H10W 72/387; H10W 72/884; H10W 90/24; H10W 90/732; H10W 90/752; H10W 90/754

(57) ABSTRACT

A semiconductor package includes a package substrate a first semiconductor chip disposed on an upper surface of the package substrate, a dam structure disposed within the pad free region on the first surface of the first semiconductor chip, a first spacer chip attached to the upper surface of the package substrate, a plurality of second semiconductor chips stacked on the first spacer chip and the first semiconductor chip using adhesive films, first bonding wires electrically connecting each of the first chip pads of the first semiconductor chip to each of first substrate pads of the package substrate, respectively, and a molding covering the first spacer chip, the first semiconductor chip, and the plurality of second semiconductor chips. The first semiconductor chip includes a pad region on which the first chip pads are disposed and a pad free region. The spacer chip is spaced apart from the first semiconductor chip along a first direction.

### CROSS-REFERENCE TO RELATED APPLICATION(S)

This application claims priority under 35 U.S.C. § 119 to Korean Patent Application No. 10-2024-0135686, filed on Oct. 27, 2024 in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a semiconductor package including a dam structure.

### DISCUSSION OF THE RELATED ART

In a multi-chip package (MCP), dolmen-shaped spacer chips are placed around a small-sized controller chip to stack memory chips on the controller chip. The upper memory chips are then attached to the controller chip and the spacer chip using an adhesive film, such as a die attach film (DAF), by a die attach process. However, if an upper surface of the controller chip has a pad-free region, on which chip pads for bonding wires are not present, there is a risk that a portion of the DAF, which becomes fluid under the high pressure and temperature in the die attach process, could flow through the pad-free region disposed on the upper surface of the controller chip. The flow can then invade a relatively narrow dolmen tunnel, causing issues such as an underfilling of a molding material and defects like chip cracks.

### SUMMARY

Example embodiments provide a method of manufacturing the semiconductor package.

According to example embodiments, a semiconductor package includes a package substrate. A first semiconductor chip is disposed on an upper surface of the package substrate such that a first surface on which first chip pads are formed faces upward. The first semiconductor chip includes a pad region on which the first chip pads are disposed and a pad free region on which the first chip pads are not disposed. A dam structure is disposed within the pad free region on the first surface of the first semiconductor chip. A first spacer chip is attached to the upper surface of the package substrate. The spacer chip is spaced apart from the first semiconductor chip along a first direction. A plurality of second semiconductor chips is stacked on the first spacer chip and the first semiconductor chip using adhesive films. First bonding wires electrically connect each of the first chip pads of the first semiconductor chip to each of first substrate pads of the package substrate, respectively. A molding is disposed on the package substrate and the molding covers the first spacer chip, the first semiconductor chip, and the plurality of second semiconductor chips.

According to example embodiments, a semiconductor package includes a package substrate. A first semiconductor chip is disposed on an upper surface of the package substrate such that a first surface on which first chip pads are formed faces upward. A dam structure is disposed within a pad free region on the first surface of the first semiconductor chip, wherein the pad free region does not include first chip pads therein. A first spacer chip is attached to the upper surface of the package substrate, wherein the first spacer chip is spaced apart from the first semiconductor chip along a first direction. A plurality of second semiconductor chips is sequentially stacked on the first spacer chip using adhesive films. First bonding wires are electrically connecting each of the first chip pads of the first semiconductor chip to each of first substrate pads of the package substrate, respectively. Second bonding wires are electrically connecting each of second chip pads of the plurality of second semiconductor chips to each of second substrate pads of the package substrate, respectively. A molding is disposed on the package substrate, the first semiconductor chip and the plurality of second semiconductor chips. A lowermost second semiconductor chip among the plurality of second semiconductor chips is attached to the first semiconductor chip by a first adhesive film among the adhesive films. The dam structure is embedded in the first adhesive film.

According to example embodiments, a semiconductor package includes a package substrate extends in a first direction and includes a plurality of substrate pads disposed on an upper surface thereof. A first semiconductor chip is disposed on the upper surface of the package substrate such that a first surface where first chip pads are formed faces upward. The first semiconductor chip includes a pad region on which the first chip pads are disposed and a pad free region on which the first chip pads are not disposed. A dam structure is disposed within the pad free region on the first surface of the first semiconductor chip. First and second spacer chips are attached to the upper surface of the package substrate, and the first and second spacer chips are spaced apart from each other along the first direction with the first semiconductor chip interposed between the first and second spacer chips. Third and fourth spacer chips are attached to the upper surface of the package substrate, and the third and fourth spacer chips are spaced apart from each other along a second direction perpendicular to the first direction with the first semiconductor chip interposed between the third and fourth spacer chips. A plurality of second semiconductor chips is sequentially stacked on the first, second, third and fourth spacer chips by adhesive films. First bonding wires are electrically connecting each of the first chip pads of the first semiconductor chip to each of the substrate pads, respectively. Second bonding wires are electrically connecting each of second chip pads of the plurality of second semiconductor chips to each of the substrate pads, respectively. A molding is disposed on the package substrate covering the first, second, third and fourth spacer chips, the first semiconductor chip, and the plurality of second semiconductor chips. A lowermost second semiconductor chip among the plurality of second semiconductor chips is attached to the first semiconductor chip by a first adhesive film among the adhesive films. The dam structure is embedded in the first adhesive film.

According to example embodiments, a method of manufacturing semiconductor package includes forming a package substrate, placing a first semiconductor chip disposed on an upper surface of the package substrate and having a pad region and a pad free region in which first chip pads are not provided, disposing a dam structure within the pad free region on an upper surface of the first semiconductor chip, attaching a first spacer chip to the upper surface of the package substrate, sequentially stacking a plurality of second semiconductor chips on the first spacer chip by adhesive films to cover the first semiconductor chip, forming first bonding wires electrically connecting first chip pads of the first semiconductor chip to first substrate pads of the package substrate, forming a molding member on the package substrate to cover the first spacer chip, the first semiconductor chip, and the plurality of second semiconductor chips BRIEF DESCRIPTION OF THE DRAWINGS A more complete appreciation of the present disclosure and many of the attendant aspects thereof will be readily obtained as the same becomes better understood by reference to the following detailed description when considered in connection with the accompanying drawings, wherein:

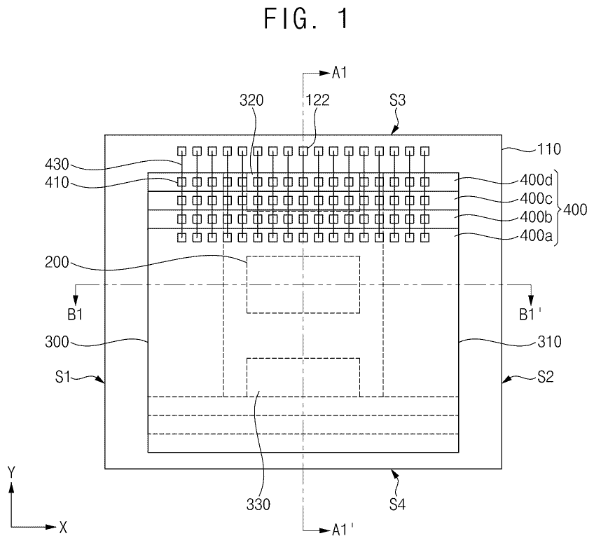

FIG. 1 is a plan view illustrating a semiconductor package in accordance with example embodiments of the present disclosure.

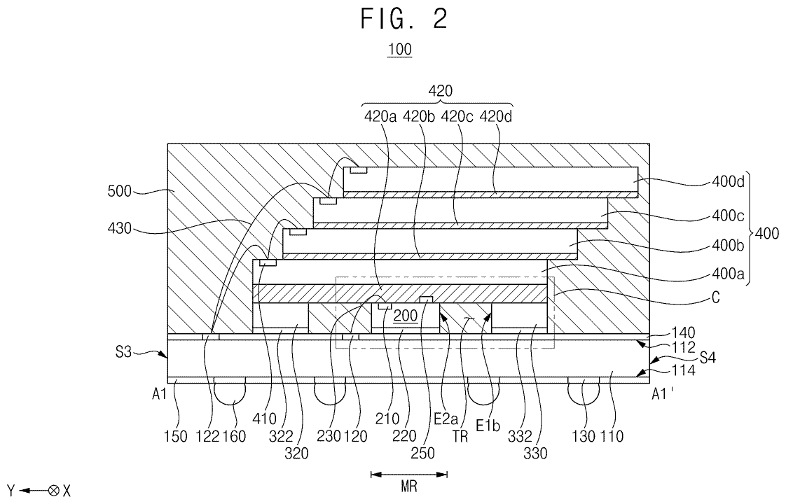

FIG. 2 is a cross-sectional view taken along the line A1-A1′ in FIG. 1.

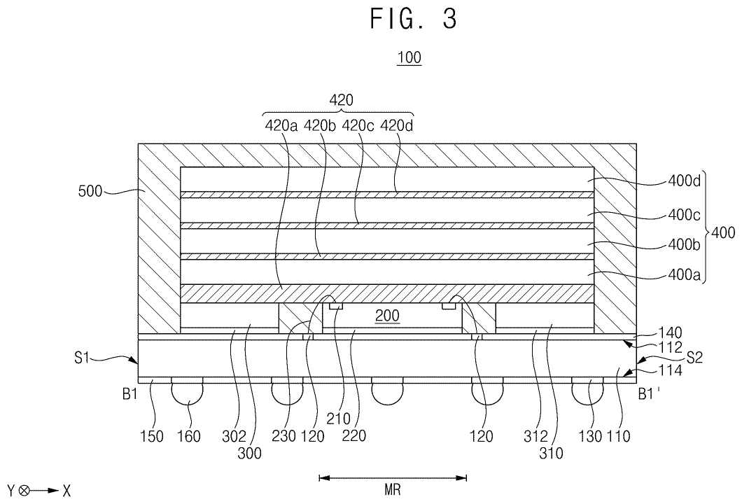

FIG. 3 is a cross-sectional view taken along the line B1-B1′ in FIG. 1.

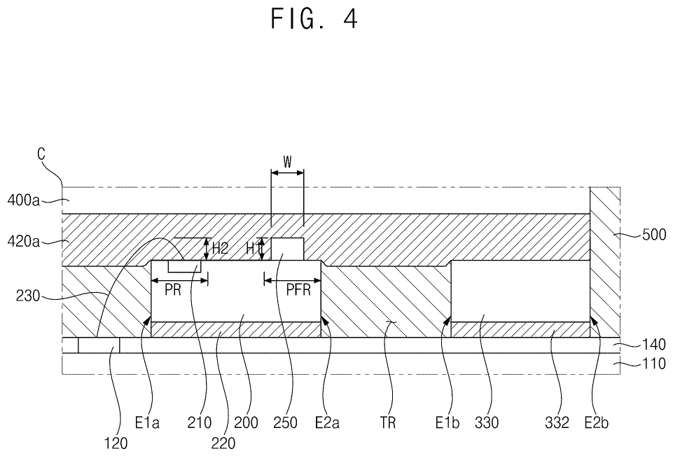

FIG. 4 is an enlarged cross-sectional view illustrating portion ‘C’ in FIG. 2.

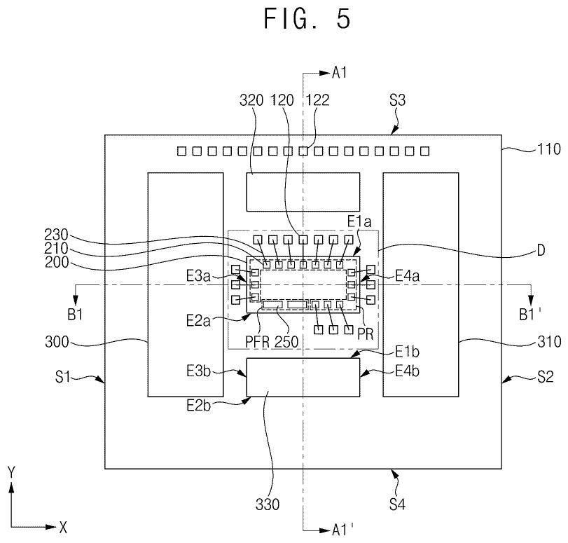

FIG. 5 is a plan view illustrating a first semiconductor chip and first to fourth spacer chips on a package substrate of FIG. 1.

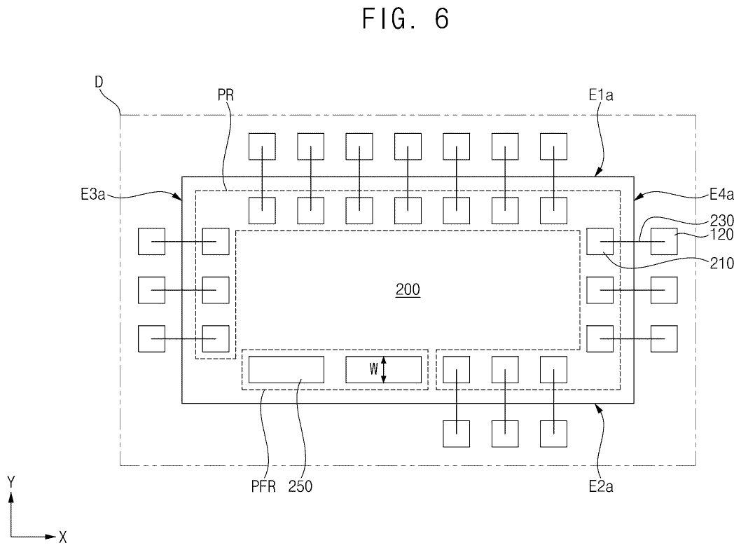

FIG. 6 is an enlarged plan view illustrating portion ‘D’ in FIG. 5.

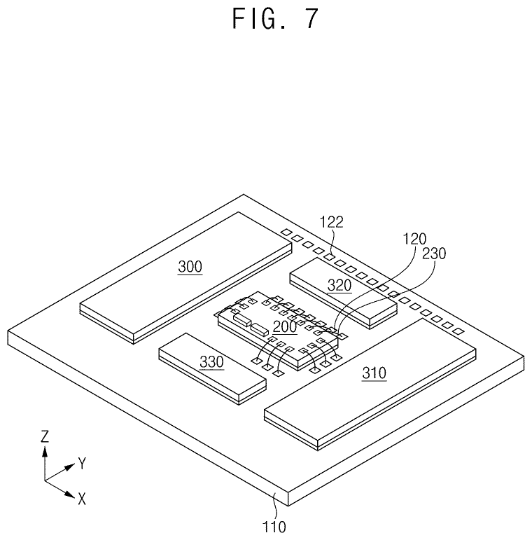

FIG. 7 is a perspective view of FIG. 5.

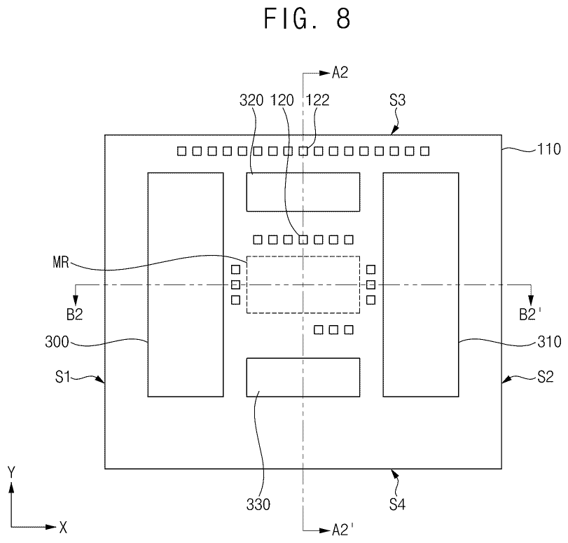

FIGS. 8, 9, 10, 11, 12, 13, 14, 15, 16, 17, 18, 19, 20, 21, and 22 are views illustrating a method of manufacturing a semiconductor package in accordance with example embodiments of the present disclosure.

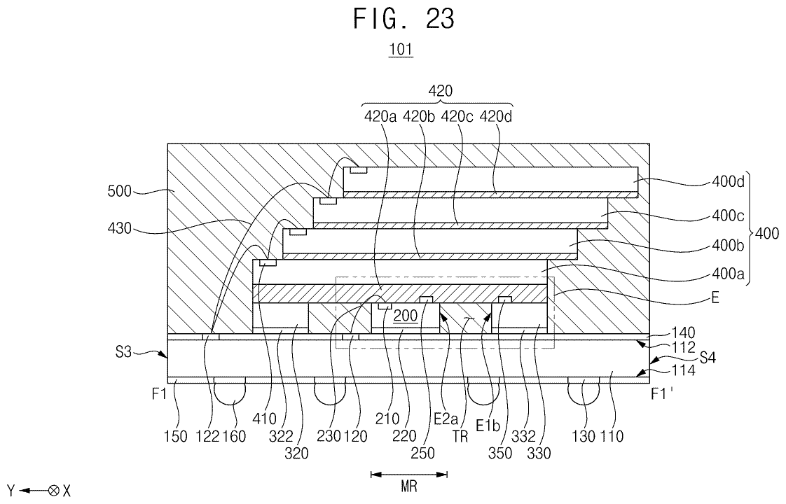

FIG. 23 is a cross-sectional view illustrating a semiconductor package in accordance with example embodiments of the present disclosure.

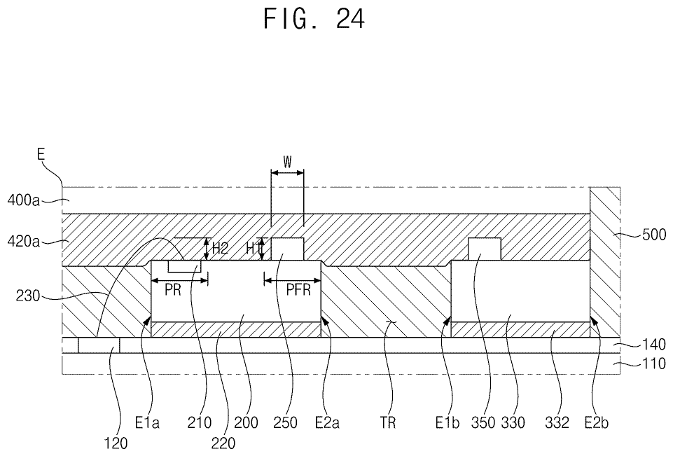

FIG. 24 is an enlarged cross-sectional view illustrating portion ‘E’ in FIG. 23.

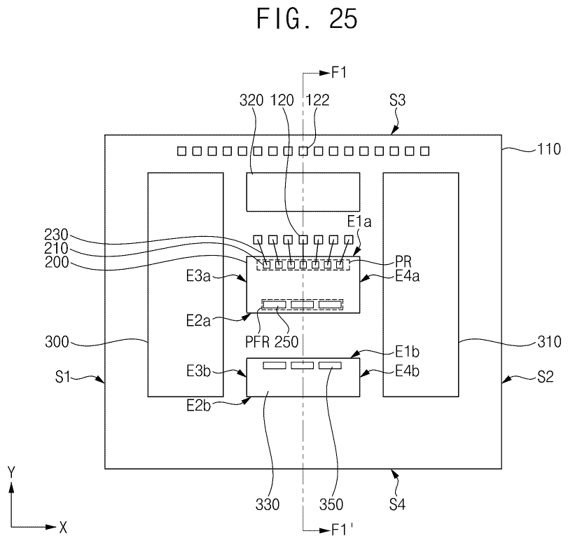

FIG. 25 is a plan view illustrating a first semiconductor chip and first to fourth spacer chips on a package substrate in FIG. 23.

### DETAILED DESCRIPTION

Hereinafter, example embodiments of the present disclosure will be explained in detail with reference to the accompanying drawings.

Embodiments of the present disclosure relate to a semiconductor device including one or more dam structures.

In manufacturing a multi-chip package (MCP), multiple chips, such as a controller chip and memory chips, need to be attached together using an adhesive film. For example, the adhesive film may be a die attach film (DAF), which is applied during a process that involves high temperature and pressure, causing the DAF to become fluid and flow.

Because the DAF may become fluid under high pressure and temperature, when the DAF is applied to bond the chips, it may flow into a pad-free region where chip pads to which bonding wires are bonded are not formed. Then, the fluid DAF may flow through the pad-free region and into a dolmen tunnel between the controller chip and the adjacent spacer chip, causing undesirable effects such as underfilling of a molding material or defects including chip cracks.

According to embodiments of the present disclosure, the semiconductor device may include the dam structure disposed on an upper surface of a first semiconductor chip in a pad-free region.

According to embodiments of the present disclosure, second semiconductor chips may be attached to the first semiconductor chip using the adhesive film, applied during the die attach process. The dam structure may be covered by the adhesive film.

According to embodiments of the present disclosure, the dam structure may act as a barrier and may prevent the fluid DAF from flowing into a dolmen tunnel area during the die attach process. As a result, the molding material may effectively fill the dolmen tunnel during the molding process. In addition, the dam structure may apply sufficient pressure to bond the chips together, preventing the molding material from leaking between the first semiconductor chip and the adhesive film.

FIG. 1 is a plan view illustrating a semiconductor package in accordance with example embodiments of the present disclosure. FIG. 2 is a cross-sectional view taken along the line A1-A1′ in FIG. 1. FIG. 3 is a cross-sectional view taken along the line B1-B1′ in FIG. 1. FIG. 4 is an enlarged cross-sectional view illustrating portion ‘C’ in FIG. 2. FIG. 5 is a plan view illustrating a first semiconductor chip and first to fourth spacer chips on a package substrate of FIG. 1. FIG. 6 is an enlarged plan view illustrating portion ‘D’ in FIG. 5. FIG. 7 is a perspective view of FIG. 5.

Referring to FIGS. 1 to 7, a semiconductor package 100 may include a package substrate 110, a first semiconductor chip 200, at least one dam structure 250, at least one spacer chip 300, 310, 320, and 330, a plurality of second semiconductor chips 400, and a molding 500. The semiconductor package 100 may further include conductive connecting members 230 and 430 that electrically connect the first semiconductor chip 200 and the plurality of second semiconductor chip 400 to the package substrate 110. In addition, the semiconductor package 100 may further include external connection members 160.

The semiconductor package 100 may be a multi-chip package (MCP) such as a universal flash storage (UFS) including different types of semiconductor chips 200 and 400. The semiconductor package 100 may be a System In Package (SIP) including a plurality of semiconductor chips 200 and 400 stacked or arranged in one package to perform all or most of the functions of an electronic system.

In example embodiments of the present disclosure, the package substrate 110 may include an upper surface 112 and a lower surface 114 opposite to the upper surface 112. For example, the package substrate 110 may include a printed circuit board (PCB), a flexible substrate, a tape substrate, etc. The printed circuit board may be a multilayer circuit board having vias and various circuits therein. The package substrate 110 may include internal wires that serve as channels for electrical connection between the first semiconductor chip 200 and the second semiconductor chip 400.

The package substrate 110 may include a first side portion S1 and a second side portion S2 extending in a second direction (Y direction), which is perpendicular to the upper surface 112 of the package substrate 110, and facing each other, and a third side portion S3 and a fourth side portion S4 extending in a direction parallel with a first direction (X direction), which is perpendicular to the second direction, and facing each other.

The package substrate 110 may include a chip mounting region MR in a central region. The chip mounting region MR may be a region where the first semiconductor chip 200 as a controller chip is mounted. The chip mounting region MR may have a rectangular shape.

The package substrate 110 may include first substrate pads 120 arranged adjacent to the chip mounting region MR and second substrate pads 122 arranged along the third side portion S3 of the package substrate 110. For example, the first substrate pads 120 may be arranged between the second substrate pads 122 and the chip mounting region MR. The first and second substrate pads 120 and 122 may be respectively connected to the wires. The wires may extend along the upper surface 112 of the package substrate 110 or inside the package substrate 110. For example, at least a portion of the wire may serve as the substrate pad, acting as a landing pad.

The number, shape, and arrangement of the substrate pads are provided as examples, and it will be understood that the present inventive concept is not necessarily limited thereto.

A first insulation layer 140 may be disposed on the upper surface 112 of the package substrate 110 and may expose the first and second substrate pads 120 and 122. For example, the first insulation layer 140 may cover the entire upper surface 112 of the package substrate 110 except where the first and second substrate pads 120 and 122 are disposed. The first insulation layer 140 may include, for example, a solder resist.

In example embodiments of the present disclosure, the first semiconductor chip 200 may be mounted on the chip mounting region MR of the package substrate 110. The first semiconductor chip 200 may be mounted on the package substrate 110 by a wire bonding method. The first semiconductor chip 200 may be arranged such that a second (backside) surface opposite to a first surface, i.e., an active surface on which first chip pads 210 are formed, faces the package substrate 110. The first semiconductor chip 200 may include a pad region PR in which the first chip pads 210 are arranged and a pad free region PFR defined by the pad region PR. The first chip pads 210 might not be arranged in the pad free region PFR.

When viewed in plan view, the first semiconductor chip 200 may have a quadrilateral shape having four sides. The first semiconductor chip 200 may include a first side surface E1a and a second side surface E2a that extend in a direction parallel to the first direction (X direction) and face each other, and a third side surface E3a and a fourth side surface E4a that extend in a direction parallel to the second direction (Y direction) and face each other.

The pad region PR and the pad free region PFR may be provided in a peripheral region of the first semiconductor chip 200. For example, the pad region PR may extend along the first side surface E1a, the second side surface E2a, the third side surface E3a, and the fourth side surface E4a of the first semiconductor chip 200. The pad region PR may be provided in the peripheral region adjacent to a first portion of the second side surface E2a of the first semiconductor chip 200. The pad free region PFR may be positioned in the peripheral region adjacent to a second portion of the second side surface E2a of the first semiconductor chip 200 excluding the pad region PR.

The first chip pads 210 may be arranged within the pad region PR on the first surface of the first semiconductor chip 200. The first chip pads 210 may be spaced apart from each other along one side within the peripheral region of the first semiconductor chip 200.

The first semiconductor chip 200 may be a logic chip including a logic circuit. The logic chip may be a controller that controls memory chips. The first semiconductor chip 200 may be a processor chip such as an application-specific integrated circuit (ASIC) and an application processor (AP) serving as a host such as central processing unit (CPU), graphics processing unit (GPU), or system on chip (SOC).

The first semiconductor chip 200 may be attached to the package substrate 110 by an adhesive film 220. The first chip pads 210 of the first semiconductor chip 200 may be connected to the first substrate pads 120 of the package substrate 110 by first bonding wires 230, which function as conductive connection members.

For example, a thickness of the first semiconductor chip 200 may range from about 40 μm to about 100 μm. A thickness of the adhesive film 220 may range from about 5 μm to about 20 μm. A height of the first semiconductor chip 200, measured from the upper surface 112 of the package substrate 110, may range from about 45 μm to about 120 μm.

In example embodiments of the present disclosure, a dam structure 250 may be disposed within the pad free region PFR on the first surface of the first semiconductor chip 200. The dam structure 250 may extend along the X direction, one side of the first semiconductor chip 200. For example, two dam structures 250 may be spaced apart from each other along the second side surface E2a of the first semiconductor chip 200. A height H1 of the dam structure 250 may range from about 5 μm to about 70 μm. A width W of the dam structure 250 may range from about 20 μm to about 60 μm. The width W of the dam structure 250 may be equal to or greater than a width of the first chip pad 210. A loop height H2 of the first bonding wire 230 from the first surface of the first semiconductor chip 200 may be equal to or greater than the height H1 of the dam structure 250. The height H1 and width W1 of the dam structure, an extending length and the number of the dam structures may be determined in consideration of an area of the pad free region PFR, thicknesses and properties of an adhesive film 220 and the molding 500 to be described below, and a spacing distance between the first semiconductor chip 200 and the spacer chips 300, 310, 320 and 330.

The dam structure 250 may be formed on the first surface of the first semiconductor chip 200 by a deposition process. The dam structure 250 may be formed by a chemical vapor deposition process. The dam structure 250 may include a metal nitride. For example, the dam structure 250 may include titanium nitride (TiN), tantalum nitride (Ta), boron nitride (BN), chromium nitride (CrN), etc. The dam structure 250 may have Young's Modulus ranging from about 250 GPa to about 400 GPa.

In example embodiments of the present disclosure, first, second, third and fourth spacer chips 300, 310, 320 and 330 may be disposed on the package substrate 110 and may surround the first semiconductor chip 200, which is disposed on the chip mounting region MR. The first, second, third and fourth spacer chips 300, 310, 320 and 330 may be attached to the upper surface 112 of the package substrate 110 by adhesive films 302, 312, 322 and 332 and may be spaced apart from each other. When viewed in plan view, each of the first, second, third and fourth spacer chips 300, 310, 320 and 330 may have a quadrilateral shape having four sides.

The first and second spacer chips 300 and 310 may be spaced apart from each other along the first direction (X direction) with the chip mounting area MR interposed between the first and second spacer chips 300 and 310. The third and fourth spacer chips 320 and 330 may be spaced apart from each other along the second direction (Y direction) with the chip mounting region MR interposed between the third and fourth spacer chips 320 and 330. The first spacer chip 300 may be disposed adjacent to the first side portion S1, the second spacer chip 310 may be disposed adjacent to the second side portion S2, the third spacer chip 320 may be disposed adjacent to the third side portion S3, and the fourth spacer chip 330 may be disposed adjacent to the fourth side portion S4. A dolmen tunnel TR may be formed between the first semiconductor chip 200 and the first to fourth spacer chips 300, 310, 320, 330 facing the first semiconductor chip 200. For example, the dolmen tunnel TR may surround the part of the first semiconductor chip 200 and the first to fourth spacer chips 300, 310, 320, 330.

The height of the first semiconductor chip 200, measured from the upper surface 112 of the package substrate 110, may be equal to or greater than the heights of the first, second, third and fourth spacer chips 300, 310, 320, 330.

In example embodiments of the present disclosure, the fourth spacer chip 330 may include a first side surface E1b facing the first semiconductor chip 200 and a second side surface E2b opposite to the first side surface E1b. For example, the second side surface E2b of the fourth spacer chip 330 may be disposed further away from the first semiconductor chip 200 than the first side surface E1b of the fourth spacer chip 330. The first side surface E1b and the second side surface E2b may each extend along the first direction (X direction). The second side surface E2a of the first semiconductor chip 200 may face the first side surface E1b of the fourth spacer chip 330. The dam structure 250 disposed on the first semiconductor chip 200 may face the first side surface E1b of the fourth spacer chip 330.

In example embodiments of the present disclosure, the plurality of second semiconductor chips 400 may be attached to the first, second, third and fourth spacer chips 300, 310, 320 and 330 using adhesive films 420. A lowermost second semiconductor chip 400a among the plurality of second semiconductor chips 400 may be attached to the first, second, third and fourth spacer chips 300, 310, 320 and 330 using a first adhesive film 420a. The remaining second semiconductor chips 400b, 400c and 400d among the plurality of second semiconductor chips 400 may be sequentially attached on the lowermost second semiconductor chip 400a using second adhesive films 420b, 420c and 420d.

The second semiconductor chip 400 may include a memory chip including a memory circuit. For example, the second semiconductor chip 400 may include a volatile memory device such as a static random-access memory (SRAM) device, a dynamic random-access memory (DRAM) device, etc. and a nonvolatile memory device such as a flash memory device, a phase-change random-access memory (PRAM) device, a magnetoresistive random-access memory (MRAM) device, a resistive random-access memory (RRAM) device, etc.

The lowermost second semiconductor chip 400a may be attached on the first, second, third and fourth spacer chips 300, 310, 320 and 330 and the first semiconductor chip 200 using the first adhesive film 420a such as a die attach film (DAF) by a die attach process.

The lowermost second semiconductor chip 400a may be arranged such that a backside surface, i.e., an inactive surface opposite to a front surface on which second chip pads 410 are formed, faces the package substrate 110. When viewed in plan view, the lowermost second semiconductor chip 400a may have a quadrilateral shape having four sides.

For example, the first adhesive film 420a may be attached to the backside surface of the lowermost second semiconductor chip 400a, and the lowermost second semiconductor chip 400a to which the first adhesive film 420a is attached may be attached on the first, second, third and fourth spacer chips 300, 310, 320 and 330 and the first semiconductor chip 200 by a thermal compression process. The lowermost second semiconductor chip 400a may be pressed onto the first, second, third and fourth spacer chips 300, 310, 320, and 330 by a die attaching tool, and may be heated to a high temperature by a heater block inside a support system that supports the package substrate 110.

A thickness of the first adhesive film 420a may range from about 20 μm to about 60 μm. The first adhesive film 420a may be a wire-embedded adhesive film (film over wire, FOW). The first adhesive film 420a may cover the first bonding wires 230 having a loop height from the upper surface of the first semiconductor chip 200.

As illustrated in FIGS. 2 and 4 to 7, in example embodiments of the present disclosure, the dam structure 250 may be formed in the pad free region PFR where the first chip pads 210 to which the first bonding wires 230 are bonded are not formed. A portion of the first adhesive film 420a attached to the first semiconductor chip 200 may cover the dam structure 250.

The dam structure 250 may prevent a portion of the die attach film (DAF), which has fluidity under high pressure and temperature during the die attach process, from flowing into the narrow dolmen tunnel TR between the second side surface E2a of the first semiconductor chip 200 and the adjacent fourth spacer chip 330 through the pad free region PFR on the upper surface of the first semiconductor chip 200. Accordingly, an underfilled phenomenon of the dolmen tunnel TR region of a molding material may be prevented in a subsequent molding process.

The remaining second semiconductor chips 400b, 400c and 400d among the plurality of second semiconductor chips 400 may be sequentially attached to the lowermost second semiconductor chip 400a by second adhesive films 420b, 420c and 420d. The remaining second semiconductor chips 400b, 400c and 400d may be sequentially attached to the lowermost second semiconductor chip 400a using the second adhesive film 420b, 420c and 420d such as a die attach film (DAF) by a die attach process. Thicknesses of the second adhesive films 420b, 420c and 420d may range from about 10 μm to about 20 μm.

A planar area of the second semiconductor chip 400 may be greater than a planar area of the first semiconductor chip 200. Accordingly, the second semiconductor chips 400a, 400b, 400c and 400d may be supported and mounted on the package substrate 110 by the first, second, third and fourth spacer chips 300, 310, 320 and 330.

The plurality of second semiconductor chips 400a, 400b, 400c and 400d may be arranged in an offset stack, on top of each other, with each second semiconductor chips 400a, 400b, 400c and 400d being misaligned in an offset manner. For example, the second semiconductor chips 400a, 400b, 400c, and 400d may be stacked in a cascade structure. The second semiconductor chips 400a, 400b, 400c and 400d may be sequentially offset and aligned along a first lateral direction (X direction) of the package substrate 110.

The number, sizes, arrangements, etc. of the second semiconductor chips 400 are provided as examples, and it will be understood that the present inventive concept is not necessarily limited thereto. Additionally, although only a few second chip pads 410 are illustrated in the figures, the structures, shapes, and arrangements of the second chip pads 410 are provided as examples, and it will be understood that the present inventive concept is not necessarily limited thereto.

In example embodiments of the present disclosure, the second semiconductor chips 400 may be electrically connected to the package substrate 110 by second bonding wires 430 as conductive connecting members.

For example, the second chip pads 410 of the second semiconductor chips 400 may be connected to the second substrate pads 122 disposed on the upper surface 112 of the package substrate 110 by the second bonding wires 430.

In example embodiments of the present disclosure, the molding 500 may cover the first, second, third and fourth spacer chips 300, 310, 320 and 330, the second semiconductor chips 400 and the second bonding wires 430 disposed on the upper surface 112 of the package substrate 110. The molding 500 may include a thermosetting resin, for example, epoxy molding compound (EMC).

In example embodiments of the present disclosure, external connection pads 130 for providing electrical signals may be formed on the lower surface 114 of the package substrate 110. The external connection pads 130 may be exposed by a second insulating layer 150. The second insulating layer 150 may include a silicon oxide layer, a silicon nitride layer, or a silicon oxynitride layer. An external connection member 160 may be disposed on the external connection pad 130 of the package substrate 110 and may provide an electrical connection with an external device. For example, the external connection member 160 may be a solder ball. The semiconductor package 100 may be mounted on a module substrate via the external connection member 160, such as the solder balls, and may provide a memory module.

The semiconductor package 100 may include the first semiconductor chip 200 disposed on the package substrate 110 and having the pad free region PFR in which the first chip pads 210 are not formed, the dam structure 250 disposed within the pad free region PFR on the upper surface of the first semiconductor chip 200, the fourth spacer chip 330 that is spaced apart from the first semiconductor chip 200 along the second direction (Y direction) disposed on the package substrate 110, the first bonding wires 230 electrically connecting the first chip pads 210 of the first semiconductor chip 200 to the first substrate pads 120 of the package substrate 110, the plurality of second semiconductor chips 400 sequentially stacked on the fourth spacer chip 330 by the adhesive films 420 to cover the first semiconductor chip 200, and the molding 500 covering the first semiconductor chip 200, the fourth spacer chip 330 and the plurality of second semiconductor chips 400 disposed on the package substrate 110.

The lowermost second semiconductor chip 400a among the plurality of second semiconductor chips 400 may be disposed on the first semiconductor chip 200 by the first adhesive film 420a among the adhesive films 420, and the dam structure 230 may be embedded in or covered by the first adhesive film 420a.

The dam structure 250 may prevent a portion of the die attach film (DAF) from flowing into the narrow dolmen tunnel TR between the first semiconductor chip 200 and the fourth spacer chip 330 through the pad free region PFR disposed on the upper surface of the first semiconductor chip 200 during the die attach process. Accordingly, the molding 500 may sufficiently or completely fill the dolmen tunnel TR region. In addition, since a sufficient pressing force for die attach can be applied, the molding 500 may be prevented from penetrating between the first semiconductor chip 200 and the first adhesive film 420a.

Hereinafter, a method of manufacturing the semiconductor package of FIG. 1 will be described.

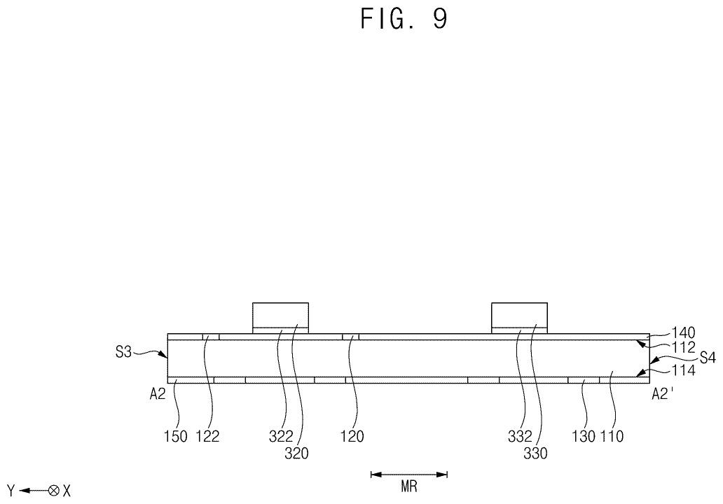

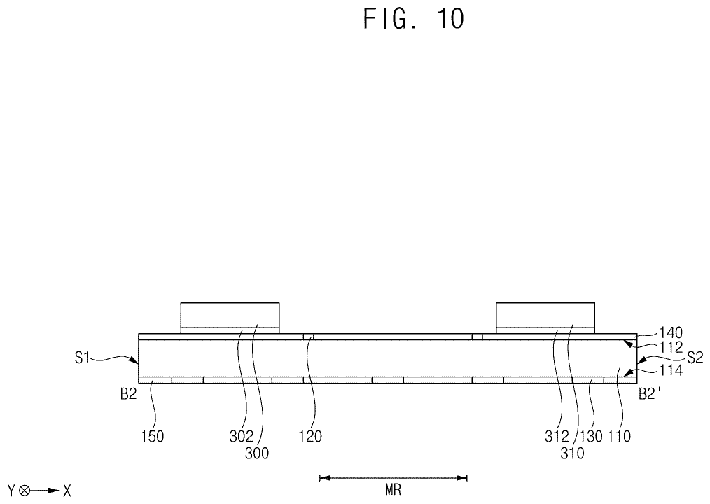

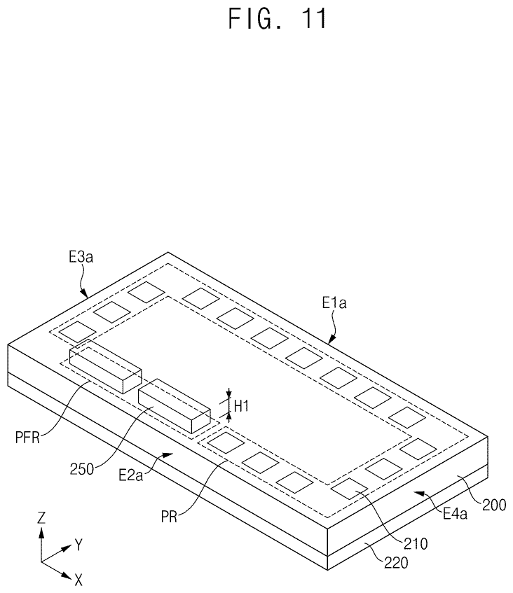

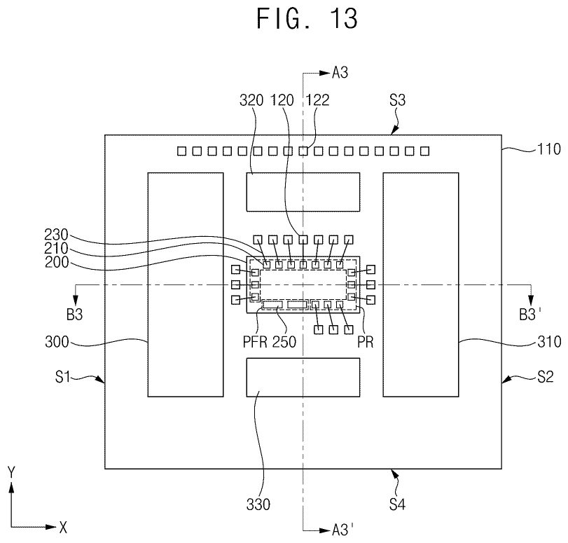

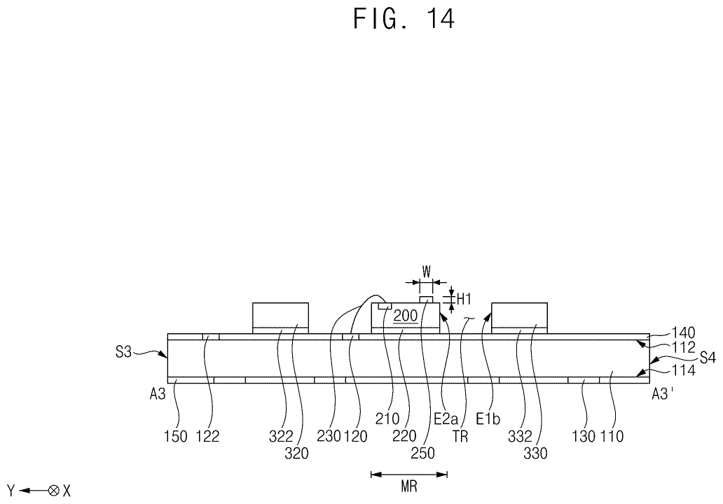

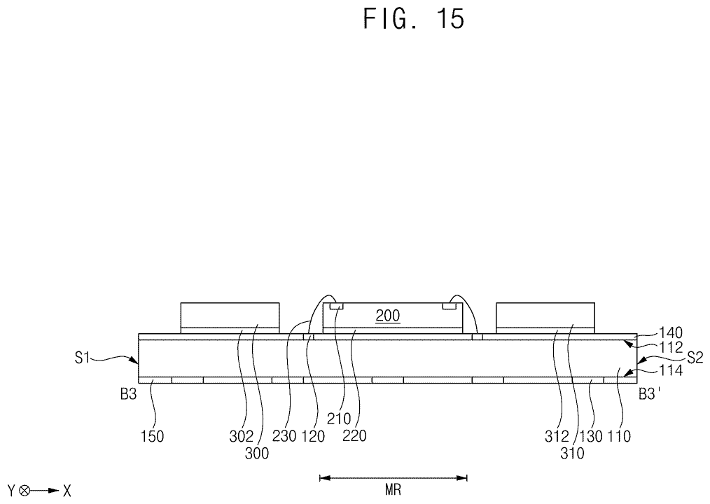

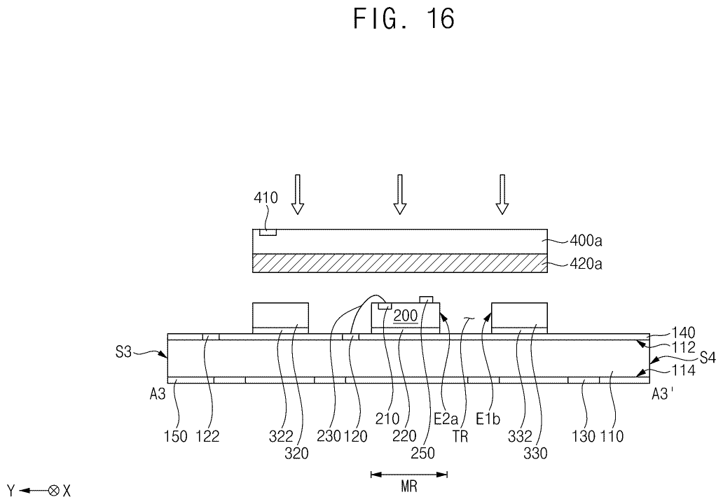

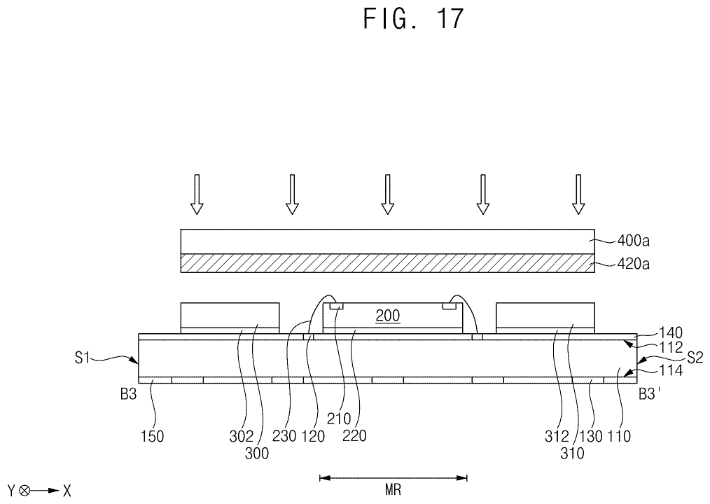

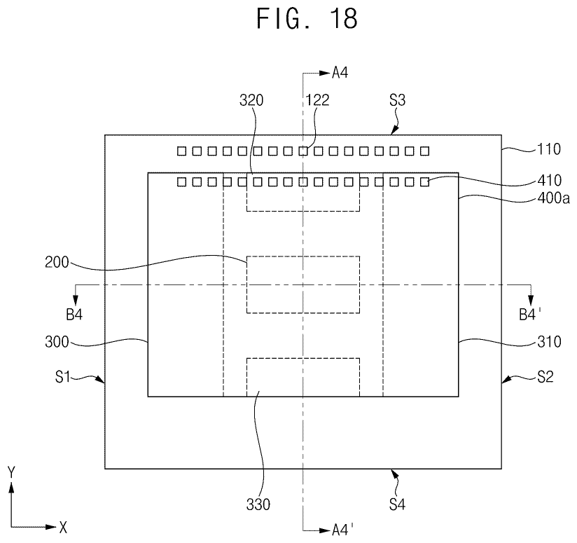

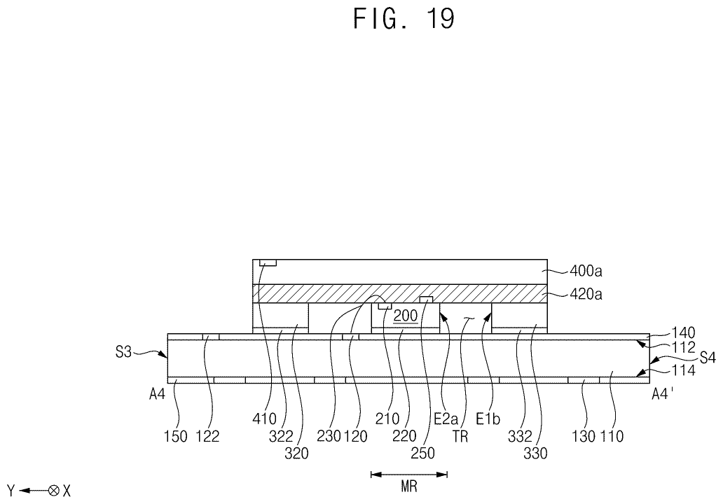

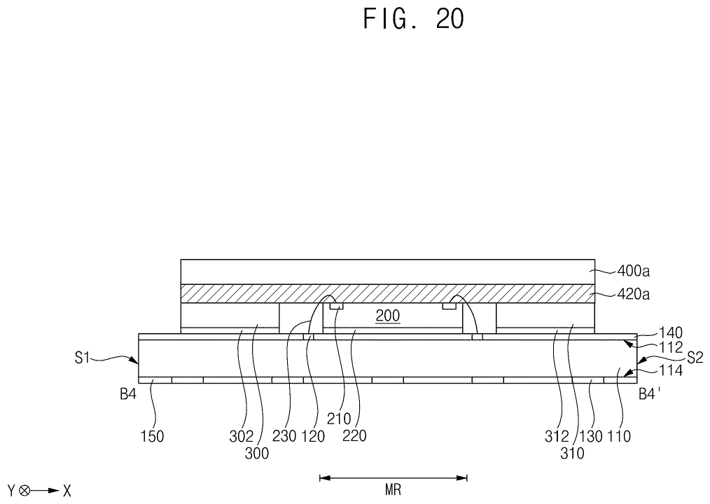

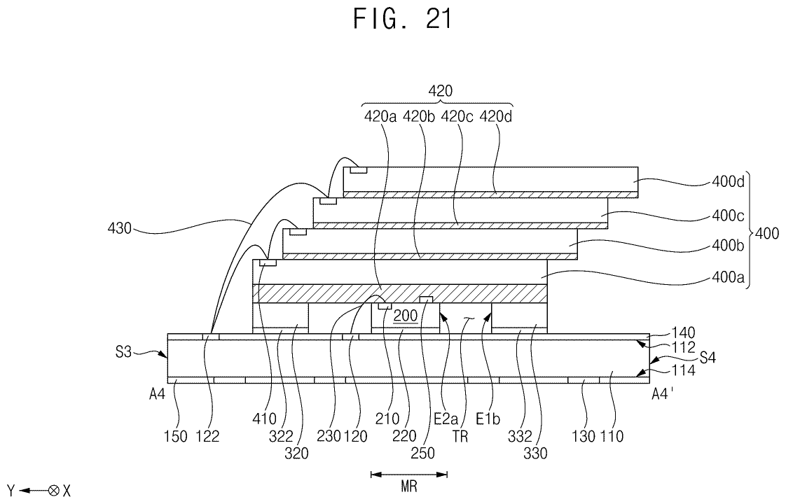

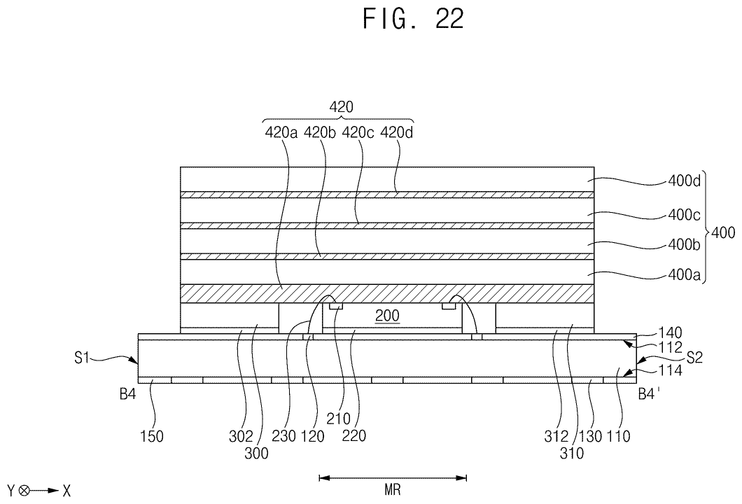

FIGS. 8 to 22 are views illustrating a method of manufacturing a semiconductor package in accordance with example embodiments of the present disclosure. FIGS. 8, 13 and 18 are plan views illustrating a method of manufacturing a semiconductor package in accordance with example embodiments of the present disclosure. FIG. 9 is a cross-sectional view taken along the line A2-A2′ in FIG. 8. FIG. 10 is a cross-sectional view taken along the line B2-B2′ in FIG. 8. FIG. 11 is a perspective view illustrating a first semiconductor chip mounted on a package substrate of FIG. 8. FIGS. 14 and 16 are cross-sectional views taken along the line A3-A3′ in FIG. 13. FIGS. 15 and 17 are cross-sectional views taken along the line B3-B3′ in FIG. 13. FIGS. 19 and 21 are cross-sectional views taken along the line A4-A4′ in FIG. 18. FIGS. 20 and 22 are cross-sectional views taken along the line B4-B4′ in FIG. 18.

Referring to FIGS. 8 to 10, at least one spacer chip 300, 310, 320, 330 may be disposed on a package substrate 110.

In example embodiments of the present disclosure, the package substrate 110 may include an upper surface 112 and a lower surface 114 opposite to the upper surface 112. For example, the package substrate 110 may be a printed circuit board (PCB). The printed circuit board may be a multilayer circuit board having vias and various circuits therein. The package substrate 110 may include internal wires serving as channels for electrical connection between the first semiconductor chip 200 and the second semiconductor chip 400.

The package substrate 110 may include a first side portion S1 and a second side portion S2 extending in a direction perpendicular to the upper surface 112 and parallel with a second direction (Y direction) and facing each other, and a third side portion S3 and a fourth side portion S4 extending in a direction parallel with the first direction (X direction) and facing each other.

The package substrate 110 may include a chip mounting region MR in a central region. The chip mounting region MR may be a region where a first semiconductor chip 200 as a controller chip is mounted. The chip mounting region MR may have a rectangular shape.

For example, a width of the package substrate 110 measured along the first direction (X direction) may range from about 10 mm to about 15 mm, and a width of the package substrate 110 measured along the second direction (Y direction) may range from about 4 mm to about 7 mm. A side of the chip mounting region MR may have a length ranging from about 2 mm to about 4 mm.

The package substrate 110 may include first substrate pads 120 disposed adjacent to the chip mounting region MR and second substrate pads 122 arranged along one side portion S3 of the package substrate 110. The first and second substrate pads 120 and 122 may be respectively connected to the wires. The wires may extend from the upper surface 112 of the package substrate 110 or inside of the package substrate 110. For example, a portion of the wire may be used as a landing pad.

Although only some substrate pads 120 and 122 are illustrated in the figures, the number, shape, and arrangement of the substrate pads are provided as examples, and it will be understood that the present inventive concept is not necessarily limited thereto.

A first insulating layer 140 may be formed on the upper surface 112 of the package substrate 110 and may expose the first and second substrate pads 120 and 122. The first insulating layer 140 may cover the entire upper surface 112 of the package substrate 110 except for the first and second substrate pads 120 and 122. For example, an upper surface of the first insulating layer 140 may be coplanar with upper surfaces of the first and second substrate pads 120 and 122. The first insulating layer 140 may include, for example, a solder resist.

In example embodiments of the present disclosure, first, second, third and fourth spacer chips 300, 310, 320 and 330 may be disposed on the package substrate 110 and may surround the chip mounting region MR. The first, second, third and fourth spacer chips 300, 310, 320 and 330 may be attached to the upper surface 112 of the package substrate 110 by using adhesive films 302, 312, 322 and 332 and may be spaced apart from each other.

The first and second spacer chips 300 and 310 may be spaced apart from each other along the first direction (X direction) with the chip mounting region MR interposed therebetween. The third and fourth spacer chips 320 and 330 may be spaced apart from each other along the second direction (Y direction) with the chip mounting region MR interposed therebetween. The first, second, third and fourth spacer chips 300, 310, 320, and 330 may be formed by cutting a silicon wafer W during a sawing process, and then, may be attached on the upper surface 112 of the package substrate 110 using the adhesive films 302, 312, 322 and 332 by a die attach process.

Each of the first to fourth spacer chips 300, 310, 320, 330 may have a flat upper surface. Heights of the first to fourth spacer chips 300, 310, 320, 330 from the package substrate 110 may be the same.

Referring to FIGS. 11 to 15, a first semiconductor chip 200 may be mounted on the package substrate 110.

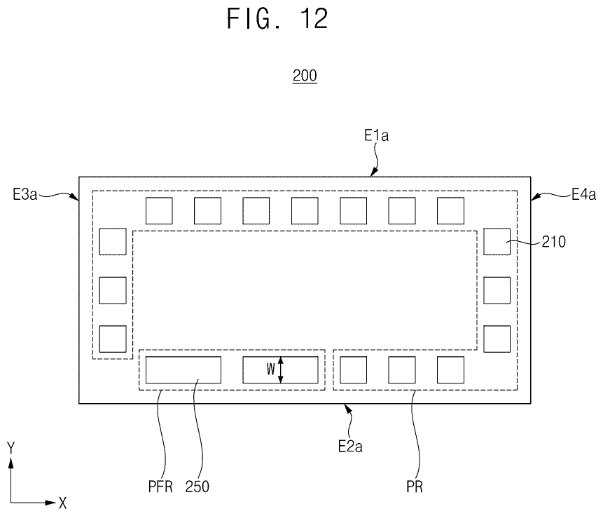

As illustrated in FIGS. 11 and 12, in example embodiments of the present disclosure, the first semiconductor chip 200 may have a first surface (front surface) on which first chip pads 210 are formed and a second surface (backside surface) opposite to the first surface. The first semiconductor chip 200 may include a pad region PR on which the first chip pads 210 are provided and a pad free region PFR defined by the pad region PR. The first chip pads 210 might not be provided in the pad free region PFR.

When viewed in plan view, the first semiconductor chip 200 may have a quadrilateral shape having four sides. The first semiconductor chip 200 may include a first side surface E1a and a second side surface E2a that extend along a direction parallel to the first direction (X direction) and face each other, and a third side surface E3a and a fourth side surface E4a that extend along a direction parallel to the second direction (Y direction) and face each other.

The pad region PR and the pad free region PFR may be provided in a peripheral region of the first semiconductor chip 200. For example, the pad region PR may extend along the first side surface E1a, the second side surface E2a, the third side surface E3a, and the fourth side surface E4a of the first semiconductor chip 200. The pad region PR may be provided in the peripheral region adjacent to a first portion of the second side surface E2a of the first semiconductor chip 200. The pad free region PFR may be positioned in the peripheral region adjacent to a second portion of the second side surface E2a of the first semiconductor chip 200 excluding the pad region PR.

The first chip pads 210 may be arranged within the pad region PR on the first surface of the first semiconductor chip 200. The first chip pads 210 may be spaced apart from each other along one side within the peripheral region of the first semiconductor chip 200.

A dam structure 250 may be disposed within the pad free region PFR on the first surface of the first semiconductor chip 200. The dam structure 250 may extend along one side of the first semiconductor chip 200. For example, two dam structures 250 may be spaced apart from each other along the second side surface E2a of the first semiconductor chip 200. A height H1 of the dam structure 250 may range from about 5 μm to about 70 μm. A width W of the dam structure 250 may range from about 20 μm to about 60 μm. The width W1 of the dam structure 250 may be equal to or greater than a width of the first chip pad 210. The height H1 and width W1 of the dam structure 250, an extending length and the number of the dam structures 250 may be determined in consideration of an area of the pad free region PFR, thicknesses and properties of an adhesive film 220 and the molding 500 to be described below, and a spacing distance between the first semiconductor chip 200 and the spacer chips 300, 310, 320, 330.

The dam structure 250 may be formed on the first surface of the first semiconductor chip 200 by a deposition process. The dam structure 250 may be formed by a chemical vapor deposition process. The dam structure 250 may include a metal nitride. For example, the dam structure 250 may include titanium nitride (TiN), tantalum nitride (Ta), boron nitride (BN), chromium nitride (CrN), etc. The dam structure 250 may have Young's Modulus ranging from about 250 GPa to about 400 GPa.

As illustrated in FIGS. 13 to 15, in example embodiments of the present disclosure, the first semiconductor chip 200 may be mounted on the package substrate 110 by an adhesive film 220. The first semiconductor chip 200 may be arranged such that second surface (backside surface) opposite to the first surface, i.e., an active surface on which the first chip pads 210 are formed, faces the package substrate 110.

The first semiconductor chip 200 may be arranged between the first and second spacer chips 300, 310 that are spaced apart from each other along the first direction (X direction). The first semiconductor chip 200 may be arranged between the third and fourth spacer chips 320, 330 that are spaced apart from each other along the second direction (Y direction). A dolmen tunnel TR may be formed between the first semiconductor chip 200 and the first to fourth spacer chips 300, 310, 320, 330 facing the first semiconductor chip 200.

The second side surface E2a of the first semiconductor chip 200 may face the first side surface E1b of the fourth spacer chip 330. Accordingly, the dam structure 250 disposed on the first semiconductor chip 200 may face the first side surface E1b of the fourth spacer chip 330.

The first semiconductor chip 200 may be mounted on the package substrate 110 by a wire bonding method. After the first semiconductor chip 200 is attached on the upper surface 112 of the package substrate 110 using the adhesive film 220, a wire bonding process may be performed and may connect the first chip pads 210 of the first semiconductor chip 200 to the first substrate pads 120 disposed on the upper surface 112 of the package substrate 110. The first chip pads 210 of the first semiconductor chip 200 may be connected to the first substrate pads 120 by first bonding wires 230 as conductive connecting members.

For example, a thickness of the first semiconductor chip 200 may range from about 40 μm to about 100 μm. A thickness of the adhesive film 220 may range from about 5 μm to about 20 μm. A height of the first semiconductor chip 200, measured from the upper surface 112 of the package substrate 110, may range from about 45 μm to about 100 μm. The height of the first semiconductor chip 200, measured from the upper surface 112 of the package substrate 110, may be equal to or greater than the heights of the first, second, third, and fourth spacer chips 300, 310, 320, 330. A loop height of the first bonding wire 230, measured from the first surface of the first semiconductor chip 200, may be equal to or greater than the height H1 of the dam structure 250.

The first semiconductor chip 200 may be a logic chip including a logic circuit. The logic chip may be a controller that controls memory chips. The first semiconductor chip 200 may be a processor chip such as an application-specific integrated circuit (ASIC) or an application processor (AP) serving as a host such as central processing unit (CPU), graphics processing unit (GPU), or system on chip (SOC).

Referring to FIGS. 16 to 22, a plurality of second semiconductor chips 400 may be attached on the first, second, third and fourth spacer chips 300, 310, 320 and 330 using adhesive films 420.

As illustrated in FIGS. 16 to 20, a lowermost second semiconductor chip 400a may be attached onto the first, second, third and fourth spacer chips 300, 310, 320 and 330 using a first adhesive film 420a. The lowermost second semiconductor chip 400a may be attached to the first, second, third and fourth spacer chips 300, 310, 320 and 330 and the first semiconductor chip 200 using the first adhesive film 420a such as a die attach film (DAF) by a die attach process.

The lowermost second semiconductor chip 400a may be disposed such that a backside surface, i.e., a non-active surface opposite to a front surface on which second chip pads 410 are formed, faces the package substrate 110. When viewed in plan view, the second semiconductor chip 400a may have a quadrilateral shape having four sides.

The second semiconductor chip 400 may include a memory chip including a memory circuit. For example, the second semiconductor chip 400 may include a volatile memory device such as an static random-access memory (SRAM) device and a dynamic random-access memory (DRAM) device, and a non-volatile memory device such as a flash memory device, a phase-change random-access memory (PRAM) device, a magnetoresistive random-access memory (MRAM) device and a resistive random-access memory (RRAM) device.

For example, the first adhesive film 420a may be attached to the backside surface of the lowermost second semiconductor chip 400a, and the lowermost second semiconductor chip 400a to which the first adhesive film 420a is attached may be attached on the first, second, third and fourth spacer chips 300, 310, 320 and 330 and the first semiconductor chip 200 by a thermal compression process. The lowermost second semiconductor chip 400a may be pressed onto the first, second, third and fourth spacer chips 300, 310, 320, and 330 by a die attaching tool, and may be heated to a high temperature by a heater block inside a support system that supports the package substrate 110.

A thickness of the first adhesive film 420a may range from about 20 μm to about 60 μm. The first adhesive film 420a may be a wire-embedded adhesive film (film over wire, FOW). The first adhesive film 420a may cover the first bonding wires 230 having a loop height from the upper surface of the first semiconductor chip 200.

As illustrated in FIG. 19, a portion of the first adhesive film 420a attached to the first semiconductor chip 200 may be provided and may cover the dam structure 250. Since the dam structure 250 is formed in the pad free region PFR where the first chip pads 210 to which the first bonding wires 230 are bonded are not formed, a portion of the die attach film (DAF) having fluidity due to high pressure and temperature in the die attach process may be prevented from flowing into the narrow dolmen tunnel TR between the second side surface E2a of the first semiconductor chip 200 and the adjacent fourth spacer chip 330 through the pad free region PFR on the upper surface of the first semiconductor chip 200. Accordingly, an underfilled phenomenon of the dolmen tunnel TR region of a molding material 500 may be prevented in a subsequent molding process.

Then, as illustrated in FIGS. 21 and 22, the remaining second semiconductor chips 400b, 400c and 400d among the plurality of second semiconductor chips 400 may be sequentially attached on the lowermost second semiconductor chip 400a using second adhesive films 420b, 420c and 420d. The remaining second semiconductor chips 400b, 400c and 400d may be sequentially attached on the lowermost second semiconductor chip 400a using second adhesive films 420b, 420c and 420d such as a die attach film (DAF) by a die attach process. A thickness of each of the second adhesive films 420b, 420c and 420d may range from about 10 μm to about 20 μm.

A planar area of the second semiconductor chip 400 may be greater than a planar area of the first semiconductor chip 200. Accordingly, the second semiconductor chips 400a, 400b, 400c and 400d may be supported and mounted on the package substrate 110 by the first, second, third and fourth spacer chips 300, 310, 320 and 330.

The plurality of second semiconductor chips 400a, 400b, 400c and 400d may be sequentially stacked on top of each other, with each second semiconductor chips 400a, 400b, 400c and 400d being misaligned in an offset manner. For example, the second semiconductor chips 400a, 400b, 400c, and 400d may be stacked in a cascade structure. The second semiconductor chips 400a, 400b, 400c and 400d may be sequentially arranged in an offset stack and aligned along a first lateral direction (−X direction) of the package substrate 110. The offset stack may refer to structure where the second semiconductor chips 400a, 400b, 400c and 400d are slightly shifted or displaced when they are stacked on top of each other.

The number, sizes, arrangements, etc. of the second semiconductor chips 400 are provided as examples, and it will be understood that the present inventive concept is not necessarily limited thereto. Additionally, although only a few second chip pads 410 are illustrated in the figures, the structures, shapes, and arrangements of the second chip pads 410 are provided as examples, and it will be understood that the present inventive concept is not necessarily limited thereto.

Then, the second semiconductor chips 400 may be electrically connected to the package substrate 110 by second bonding wires 430 as conductive connecting members.

In example embodiments of the present disclosure, a wire bonding process may be performed to connect the second chip pads 410 of the second semiconductor chips 400 to the second substrate pads 122 disposed on the upper surface 112 of the package substrate 110 by the second bonding wires 430.

Then, a molding (500, see FIGS. 2 and 3) may be formed on the upper surface 112 of the package substrate 110 to cover the first, second, third and fourth spacer chips 300, 310, 320 and 330, the second semiconductor chips 400 and the second bonding wires 430. The molding 500 may include a thermosetting resin, for example, epoxy molding compound (EMC).

The dam structure 250 may prevent a portion of the die attach film (DAF) from flowing into the narrow dolmen tunnel TR between the first semiconductor chip 200 and the fourth spacer chip 330 through the pad free region PFR on the upper surface of the first semiconductor chip 200 during the die attach process. Accordingly, the molding 500 may sufficiently fill the dolmen tunnel TR region. In addition, since a sufficient pressing force for die attach can be applied, the molding 500 may be prevented from penetrating between the first semiconductor chip 200 and the first adhesive film 420a.

Then, external connection members (130, see FIGS. 2 and 3) may be formed on external connection pads 130 on the lower surface 114 of the package substrate 110 to complete the semiconductor package 100 of FIG. 1.

For example, the external connection members 130 may include solder balls. The external connection members may be respectively formed on the external connection pads 130 of the lower surface 114 of the package substrate 110 by a solder ball attach process.

FIG. 23 is a cross-sectional view illustrating a semiconductor package in accordance with example embodiments of the present disclosure. FIG. 24 is an enlarged cross-sectional view illustrating portion ‘E’ in FIG. 23. FIG. 25 is a plan view illustrating a first semiconductor chip and first to fourth spacer chips on a package substrate in FIG. 23. FIG. 23 includes a cross-sectional portion cut along the line F1-F1′ in FIG. 24. The semiconductor package may be substantially the same as or similar to the semiconductor package described with reference to FIGS. 1 to 7 except for arrangements of dam structures and additional second dam structure. To the extent that an element has not been described in detail, it may be assumed that the element is at least similar to corresponding elements that have been described in FIGS. 1 to 7.

Referring to FIGS. 23 to 25, a semiconductor package 101 may further include at least one second dam structure 350 disposed on a fourth spacer chip 330.

In example embodiments of the present disclosure, first and second spacer chips 300 and 310 may be spaced apart from each other along a first direction (X direction) with a first semiconductor chip 200 interposed between the first and second spacer chips 300 and 310. Third and fourth spacer chips 320 and 330 may be spaced apart from each other along a second direction (Y direction) with the first semiconductor chip 200 interposed between the third and fourth spacer chips 320 and 330. The first spacer chip 300 may be disposed adjacent to a first side portion S1, the second spacer chip 310 may be disposed adjacent to a second side portion S2, the third spacer chip 320 may be disposed adjacent to a third side portion S3, and the fourth spacer chip 330 may be disposed adjacent to a fourth side portion S4. A dolmen tunnel TR may be formed between the first semiconductor chip 200 and the first to fourth spacer chips 300, 310, 320, 330 facing the first semiconductor chip 200.

The fourth spacer chip 330 may include a first side surface E1b facing the first semiconductor chip 200 and a second side surface E2b opposite to the first side surface E1b. For example, the second side surface E2b of the fourth spacer chip 330 may be disposed further away from the first semiconductor chip 200 than the first side surface E1b of the fourth spacer chip 330. The first side surface E1b and the second side surface E2b may each extend along the first direction (X direction). The second side surface E2a of the first semiconductor chip 200 may face the first side surface E1b of the fourth spacer chip 330.

In example embodiments of the present disclosure, the first semiconductor chip 200 may include a pad region PR in which the first chip pads 210 are arranged and a pad free region PFR defined by the pad region PR. The first chip pads 210 might not be provided in the pad free region PFR. For example, the pad region PR may extend along the first side surface E1a of the first semiconductor chip 200. The pad region PR may be positioned in a peripheral region adjacent to the first side surface E1a of the first semiconductor chip 200. The pad free region PFR may extend along the second side surface E2a of the first semiconductor chip 200. The pad free region PFR may be positioned in the peripheral region adjacent to the second side surface E2a of the first semiconductor chip 200.

The dam structure 250 may be disposed within the pad free region PFR on an upper surface of the first semiconductor chip 200. The dam structure 250 may be disposed adjacent to the second side surface E2a of the first semiconductor chip 200. For example, three dam structures 250 may be spaced apart from each other along the second side surface E2a of the first semiconductor chip 200.

The second dam structure 350 may be disposed on an upper surface of the fourth spacer chip 330. The second dam structure 350 may be arranged adjacent to the first side surface E1b of the fourth spacer chip 330. For example, three second dam structures 350 may be spaced apart from each other along the first side surface E1b of the fourth spacer chip 330.

The dam structure 250 disposed on the first semiconductor chip 200 may face the second dam structure 350 disposed on the fourth spacer chip 330. The second dam structure 350 may be identical to or similar to the dam structure 250.

The dam structure 250 and the second dam structure 350 may prevent a portion of a first adhesive film 420a from flowing into the narrow dolmen tunnel TR between the first semiconductor chip 200 and the fourth spacer chip 330 through the pad free region PFR disposed on the upper surface of the first semiconductor chip 200 during a die attach process. Accordingly, a molding500 may sufficiently or completely fill the dolmen tunnel TR region. In addition, since a sufficient pressing force for die attach can be applied, the molding 500 may be prevented from penetrating between the first semiconductor chip 200 and the first adhesive film 420a.

The semiconductor package 101 may include semiconductor devices such as logic devices or memory devices. The semiconductor package 101 may include logic devices such as central processing units (CPUs), main processing units (MPUs), or application processors (APs), or the like, and volatile memory devices such as dynamic random-access memory (DRAM) devices, high bandwidth memory (HBM) devices, or non-volatile memory devices such as flash memory devices, phase-change random-access memory (PRAM) devices, magnetoresistive random-access memory (MRAM) devices, resistive random-access memory (RRAM) devices, or the like.

The foregoing is illustrative of example embodiments of the present disclosure and is not to be construed as necessarily limiting thereof. Although a few example embodiments have been described, those skilled in the art will readily appreciate that many modifications are possible in example embodiments without materially departing from the novel teachings and advantages of the present invention.

What is claimed is:

1. A semiconductor package, comprising:
a package substrate;
a first semiconductor chip disposed on an upper surface of the package substrate such that a first surface on which first chip pads are formed faces upward, wherein the first semiconductor chip includes a pad region on which the first chip pads are disposed and a pad free region on which the first chip pads are not disposed;
a dam structure disposed within the pad free region on the first surface of the first semiconductor chip;
a first spacer chip attached to the upper surface of the package substrate, wherein the first spacer chip is spaced apart from the first semiconductor chip along a first direction;
a plurality of second semiconductor chips stacked on the first spacer chip and the first semiconductor chip using adhesive films;
first bonding wires electrically connecting each of the first chip pads of the first semiconductor chip to each of first substrate pads of the package substrate, respectively; and
a molding disposed on the package substrate and covering the first spacer chip, the first semiconductor chip, and the plurality of second semiconductor chips.

2. The semiconductor package of claim 1, wherein the dam structure is adjacent to a first side surface of the first semiconductor chip that faces the first spacer chip.

3. The semiconductor package of claim 2, wherein the dam structure includes a plurality of dam structures that are spaced apart from each other along the first side surface of the first semiconductor chip.

4. The semiconductor package of claim 2, further comprising:
a second dam structure disposed on an upper surface of the first spacer chip,
wherein the second dam structure is adjacent to a second side surface of the first spacer chip that faces the first side surface of the first semiconductor chip.

5. The semiconductor package of claim 1, wherein a height of the dam structure ranges from about 5 μm to about 50 μm.

6. The semiconductor package of claim 1, wherein a width of the dam structure ranges from about 20 μm to about 60 μm.

7. The semiconductor package of claim 1, wherein the dam structure includes a metal nitride.

8. The semiconductor package of claim 1, further comprising:
a second spacer chip attached to the upper surface of the package substrate, wherein the second spacer chip is spaced apart from the first spacer chip along the first direction or a second direction perpendicular to the first direction with the first semiconductor chip interposed between the first spacer chip and the second spacer chip.

9. The semiconductor package of claim 8, wherein the plurality of second semiconductor chips are arranged in an offset stack on the first spacer chip and the second spacer chip.

10. The semiconductor package of claim 1, wherein the adhesive films include a die attach film.

11. A semiconductor package, comprising:
a package substrate;
a first semiconductor chip disposed on an upper surface of the package substrate such that a first surface on which first chip pads are formed faces upward;
a dam structure disposed within a pad free region on the first surface of the first semiconductor chip, wherein the pad free region does not include first chip pads therein;
a first spacer chip attached to the upper surface of the package substrate, wherein the first spacer chip is spaced apart from the first semiconductor chip along a first direction;
a plurality of second semiconductor chips sequentially stacked on the first spacer chip using adhesive films;
first bonding wires electrically connecting each of the first chip pads of the first semiconductor chip to each of first substrate pads of the package substrate, respectively;
second bonding wires electrically connecting each of second chip pads of the plurality of second semiconductor chips to each of second substrate pads of the package substrate, respectively; and
a molding disposed on the package substrate, the first semiconductor chip and the plurality of second semiconductor chips,
wherein a lowermost second semiconductor chip among the plurality of second semiconductor chips is attached to the first semiconductor chip by a first adhesive film among the adhesive films, and
wherein the dam structure is embedded in the first adhesive film.

12. The semiconductor package of claim 11, wherein the dam structure is adjacent to a first side surface of the first semiconductor chip that faces the first spacer chip.

13. The semiconductor package of claim 12, wherein the dam structure includes a plurality of dam structures that are spaced apart from each other along the first side surface of the first semiconductor chip.

14. The semiconductor package of claim 11, wherein a height of the dam structure is less than a thickness of the first adhesive film.

15. The semiconductor package of claim 14, wherein the height of the dam structure ranges from about 5 μm to about 70 μm.

16. The semiconductor package of claim 11, wherein a width of the dam structure ranges from about 20 μm to about 60 μm.

17. The semiconductor package of claim 11, wherein the dam structure includes a metal nitride.

18. The semiconductor package of claim 11, further comprising:
a second spacer chip attached to the upper surface of the package substrate, wherein the second spacer chip is spaced apart from the first spacer chip in the first direction or a second direction perpendicular to the first direction with the first semiconductor chip interposed between the first spacer chip and the second spacer chip.

19. The semiconductor package of claim 11, wherein the adhesive films include a die attach film.

20. A semiconductor package, comprising:
a package substrate extending in a first direction, and including a plurality of substrate pads disposed on an upper surface thereof;
a first semiconductor chip disposed on the upper surface of the package substrate such that a first surface where first chip pads are formed faces upward, wherein the first semiconductor chip includes a pad region on which the first chip pads are disposed and a pad free region on which the first chip pads are not disposed;
a dam structure disposed within the pad free region on the first surface of the first semiconductor chip;
first and second spacer chips attached to the upper surface of the package substrate, wherein the first and second spacer chips are spaced apart from each other along the first direction with the first semiconductor chip interposed between the first and second spacer chips;
third and fourth spacer chips attached to the upper surface of the package substrate, wherein the third and fourth spacer chips are spaced apart from each other along a second direction perpendicular to the first direction with the first semiconductor chip interposed between the third and fourth spacer chips;
a plurality of second semiconductor chips sequentially stacked on the first, second, third and fourth spacer chips by adhesive films;
first bonding wires electrically connecting each of the first chip pads of the first semiconductor chip to each of the plurality of substrate pads, respectively;
second bonding wires electrically connecting each of second chip pads of the plurality of second semiconductor chips to each of the plurality of substrate pads, respectively; and
a molding disposed on the package substrate covering the first, second, third and fourth spacer chips, the first semiconductor chip, and the plurality of second semiconductor chips,
wherein a lowermost second semiconductor chip among the plurality of second semiconductor chips is attached to the first semiconductor chip by a first adhesive film among the adhesive films, and
wherein the dam structure is embedded in the first adhesive film.
